(19) United States
(12) Patent Application Publication
(10) Pub. No.: US 2009/0314347 A1
(43) Pub. Date: Dec. 24, 2009

(54) Solar multistage concentrator, and greenhouse

(76) Inventor: Juergen Kleinwaechter, Kandern (DE)

Correspondence Address: COLLARD & ROE, P.C., 1077 NORTHERN BOULEVARD, ROSLYN, NY, 11576, US

(21) Appl. No.: 12/311,061

(22) PCT Filed: Sep. 17, 2007
(86) PCT No.: PCT/DE2007/001659

§ 371 Date: Jul. 31, 2009

(30) Foreign Application Priority Data
Sep. 19, 2006 (DE) 10 2006 044 603.8

(51) Int. Cl. H01L 31/00; G02B 3/00; G02B 17/00; G02B 3/12

(52) U.S. Cl. 136/259; 359/793; 359/736; 359/665

(57) ABSTRACT

Disclosed is a solar multistage concentrator in which at least one imaging lens system (1) is mounted in front of a non-imaging lens system (3, 4) in such a way that both systems are an integral part of a specifically formed, light-transparent dielectric (2).

The invention relates to a solar multistage concentrator and a greenhouse.

Refractive lenses in solar technology are used either as optically imaging lenses (solid lenses or Fresnel lenses) or as optically non-imaging systems, which are usually called CPC (Compound Parabolic Concentrators) in the literature.

The imaging lenses (either linear or punctiform) image the sun in focal lines or focal points, which contain aberrations if the outline of the lenses is not exactly parabolic. The functioning of lenses follows the principle of refraction of light rays when entering an optically denser medium from an optically thinner medium and vice versa. Using punctiform concentrating lenses, the sunlight can in practice be concentrated with concentration factors of more than 10,000 (in theory up to approximately 44,000), and using linear lenses, a concentration factor of over 100 (in theory up to approximately 200) can be achieved.

Non-imaging lenses concentrate the sunlight in wedge-shaped tapered physical structures (linearly or rotationally symmetrical), wherein the sunlight entering the lens through the aperture area is reflected at the edges of the wedge by total internal reflection between the outside air and the optical material of the wedges, towards the narrower end of the wedge, where it is emitted in a concentrated, but non-imaging, form.

The edges of such linear or rotational-symmetrical “wedges” are often shaped in a parabolic form, because this leads to a structure which is shorted in comparison to straight walls, hence the name CPC (Compound Parabolic Concentrator).

In principle, very long wedges are able to concentrate the sunlight right up to the theoretical limit, if the side edges are only slightly inclined with respect to the optical axis, since the total internal reflection takes place with 100% efficiency.

In practice, this is counteracted by long construction lengths, the associated amount of material required, and the unavoidable light absorption losses in long structures that occur with real materials.

For this reason, in practice, non-imaging CPC-optical systems are used either for concentrating sunlight by a factor of up to 4 without solar tracking, and/or for producing special energy density properties in the emitting aperture. An alternative field of use is as a second stage of a concentrating mirror or of a lens with non-ideal optical imaging. In this case, the CPC provides for the second concentration of the light (i.e. as a second stage concentrator), or for homogenising the radiation flow.

The problem addressed by the invention is to improve on previous solar technology.

This problem is solved by a solar multistage concentrator according to Claim 1. The problem is also solved by a greenhouse according to Claim 22. Advantageous embodiments of the solar multistage concentrator can be found in particular in the dependent claims.

In all previously known optical concentration systems, the primary concentrator (a highly concentrating mirror or lens) is spatially separated from the downstream non-imaging stage, which means that there is air between these two stages. This has the effect that a lens system comprises three points of partial reflection loss which reduce the optical efficiency of the system; in the case of the concentrating mirror, the system comprises two points of partial reflection loss.

In the case of the lens system, these are:
partial reflection in the entry aperture,
partial reflection in the emitting aperture,
partial reflection in the input aperture of the non-imaging stage,
and in the case of the mirror system,
the partial reflection in its entry aperture and in the secondary lens.
This leads to optical losses of ≧12% for the lens system, and of ≧8% for the mirror system.

The basic idea of the multistage concentrator according to the present invention consists therefore in connecting at least one optically imaging lens integral with the downstream non-imaging lens, in such a way that only a partial reflection now takes place at the entry aperture of the system, that the radiation flow proceeds in the highly transparent dielectric until it impinges on the losslessly connected solar transducer, and is structured over the downstream stage(s) in such a way that it is optimally matched in relation to the specific demands of the solar converter in respect of its geometrical shape, its optical concentration and the energy density distribution.

Further advantages of the solar multistage concentrator according to the invention with respect to the prior art are presented using the variants described below by reference to the drawing.

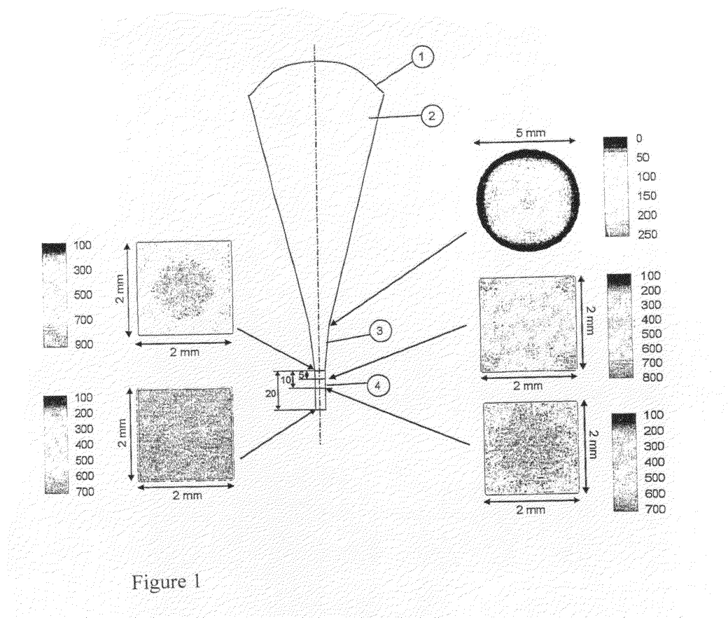

FIG. 1 shows a multistage concentrator with three stages, the function of which is to receive the sunlight incident perpendicular to its entry aperture, and to focus it onto a square emission cross-section of 4 mm² with an energy density distribution of 600 suns over the whole emission area. A first concentrator stage 1, embodied as a spherical calotte, concentrates the sunlight to the depth of the transparent dielectric medium 2. In the input area to a second stage 3, embodied as a secondary concentrator the distribution of the flow of radiation remains highly inhomogeneous—in accordance with the cauterisation of the spherical concentrator. The maximum concentration in this plane section is approximately c=260.

The secondary concentrator 3 concentrates the flow of radiation, which at its upper edge covers a square area of 8×8 mm², to the desired square cross-section of 2×2 mm². In this stage, the concentration of the still inhomogeneous radiation field rises to over c=800 in the centre, and in the outer areas to approximately c=500. In the downstream homogenising cuboid (4), an almost perfect homogenous distribution of approximately c=600 is obtained.

In this example, the multistage concentrator according to one configuration of the invention consists of a highly transparent body made of fluoropolymer with a refractive index of 1.3, which is filled with a fluoro-fluid that is also highly transparent over the whole solar immission spectrum and a refractive index of 1.3. While in stage 1 of the arrangement the quasi-parallel sunlight is refracted directly deep into the fluid and concentrated, it is further concentrated and homogenised in stages 2 and 3 by the total reflection at the outer boundary surfaces.

The relatively low refraction index of the dielectrics used leads to an elongated structure. However, since the dimensions of the whole optical system are small, this scarcely has an effect. It is advantageous however to have a low refraction index in the area of the input calotte (1), since this is therefore partly non-reflecting.

If the optical system is considered taking account of the optical material characteristics, the solar spectrum, the Fresnel losses, the dispersion and the aperture angle of the sun seen from the earth (“solar size”), with a perfect alignment of the sun (the normal vector of the aperture points to the sun), an optical efficiency of 97.3% is obtained.

If a deviation in the alignment angle of +/−0.5° is allowed (modern solar tracking systems will normally not reach this), the homogeneity in the emission area is maintained, and the efficiency is reduced to 95.8%, due to a small number of beam paths exceeding the maximum angle for total reflection.

Typically, if a high power solar cell of square cross-section is connected to the output aperture of the multistage concentrator described, a state of the art solar cell can reach a total sun/current efficiency of 0.97×0.4=0.388. (So-called triple-junction solar cells nowadays, at a light concentration of around 600 times and homogenous light distribution, achieve approximately 40% electrical efficiency, with an efficiency of 50% expected in a few years.)

The best known systems with optical elements separated by air achieve an efficiency of approximately 30%. The superiority of the multistage concentrator according to the invention is therefore based on, as described, the avoidance of reflection losses and on the synergy of the several stages with respect to concentration and homogeneity.

An important precondition for achieving the above-named efficiency rates and for the service lifetime of the photovoltaic transducer is sufficient cooling of the solar cells. A particularly effective and controllable method of doing this is to use active fluid cooling.

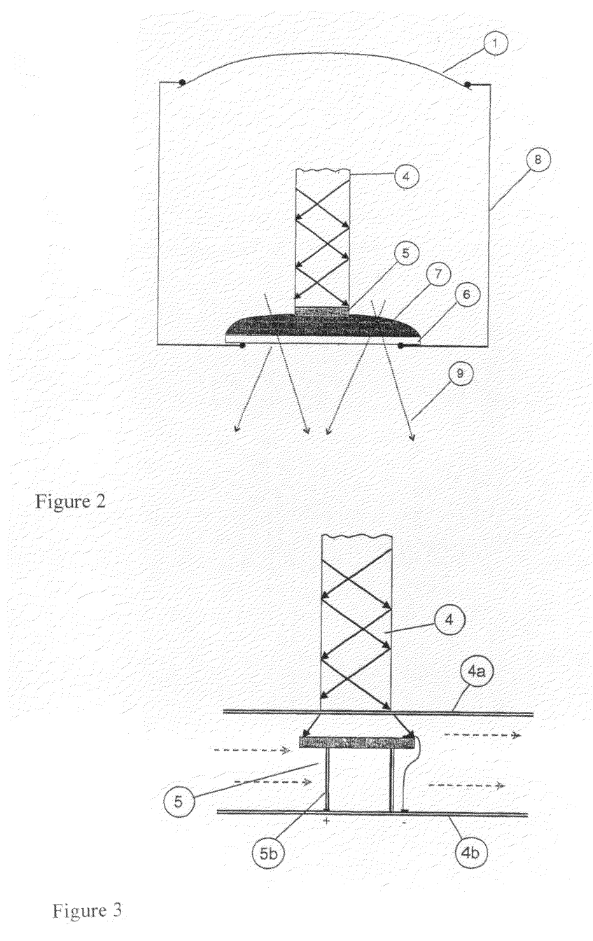

This is schematically shown in FIG. 2, where (4) represents the homogeniser wedge, (5) the solar cell connected to the emission cross-section of (4) via an optical immersion, (6) a transparent, flexurally rigid plate, to the periphery of which is a highly transparent fluoropolymer membrane (7) is fixed, so that in the created gap, a transparent dielectric fluid can circulate which cools the solar cell. This transparent cooling arrangement is connected to the multistage lens via the struts (8), and allows the diffuse component (9) of the light, which penetrates through the edges of the lens, to reach through to the empty space underneath the lens.

The multistage optical system described in the example and shown with a fluid core can also be replaced by a solid optical dielectric, such as PMMA, glass, silicone rubber etc. In this way, higher differences in the refractive index between the medium and the air can be realised, which would lead to more compact geometries of the optical system. However, in this case, the solar cell according to FIG. 2 is only cooled on the rear side, whereas in the first case the front side of the solar cell, which is only separated from the dielectric fluid of the optical system by a very thin end membrane, can transfer heat to the fluid.

In principle, according to a different variant of the idea according to the invention, the solar cell can be transparently cooled on both sides even when using a lens consisting of a solid dielectric medium. FIG. 3 shows schematically how the final stage of the lens (4), consisting of e.g. PMMA, ends in a transparent plate of the same material (4a). This plate forms—together with (4b)—a transparent double webbed plate, through which cooling fluid flows (preferably a highly transparent, radiation-proof, inert and electrically insulating fluorine liquid. The solar cell projects on a metallic strut into the region of the plate, in which the diverging beams emerging from (4) attain the size of the solar cell. The solar cell is now cooled very effectively, since fluid flows passed it dynamically from both sides, and the metallic strut provides an additional enlargement of the surface. This strut creates the electrical contact of the rear side to the lower plate, which is fitted with a conductor structure. The electrical contact to the front side of the solar cell is created by an isolated cable.

The active fluid cooling of the solar cell in the above-described manner is not only particularly effective, but it also allows the non-electrically converted portion of the radiation (approximately 60%) to be transferred into useful fluid heat (electro-thermal coupling). If triple junction solar cells are used, the cooling fluid can be heated to 80° C., without damaging the solar cells or generating large efficiency losses.

Since solar energy can be used very practically in decentralised systems, and since many small consumers in the business, agricultural and private sectors particularly need electrical energy and heat, the heat generated by the described system with high efficiency makes a substantial contribution to the economic efficiency of the whole system.

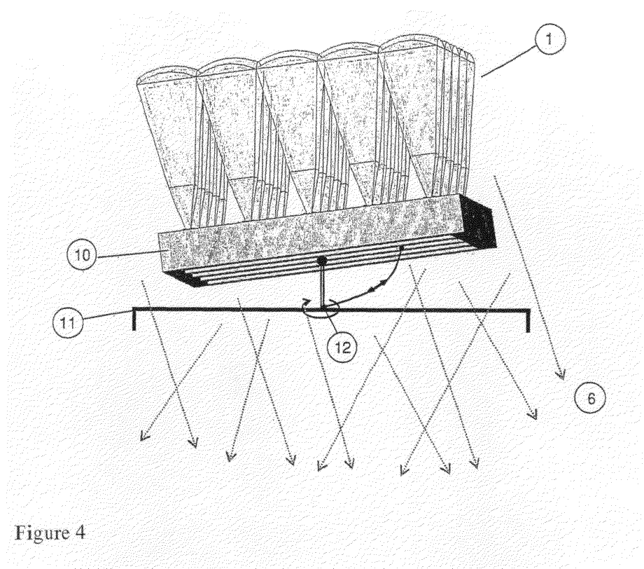

In FIG. 4, a typical possibility for the assembly of a plate-shaped cluster of n-multistage concentrators is shown. The concentrators are arranged on a carrying frame (10), which uses the gimbal-mounted bearing (12) for tracking the solar azimuth and elevation. The necessary micro-motors and control logics (using sensors and/or digital memory logic) are not described in detail, since they correspond to the prior art.

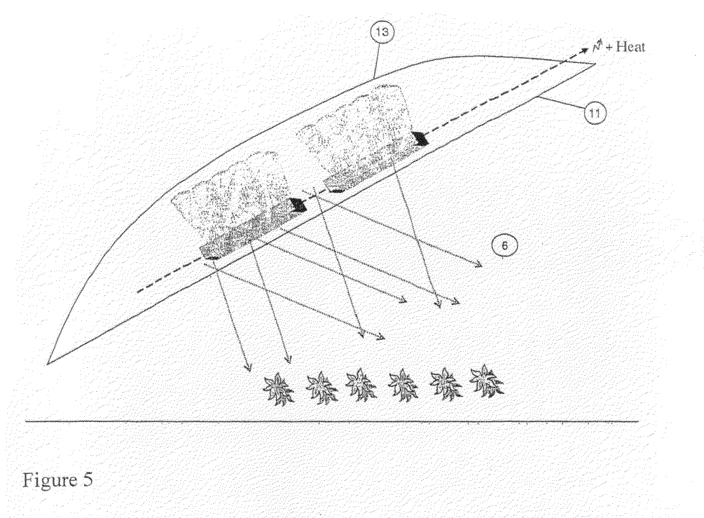

The gimballed bearing is preferably fixed on a carrier (10), the rationale of which is best seen from FIG. 5. In FIG. 4, the rays identified by reference number (6) represent the diffuse light which, after entering the lenses through the entry apertures, is not concentrated onto the focal point—as are the parallel sun rays—but passes over the edges of the arrangement into the space behind.

Since the downstream solar cells are very small, the cooling systems rather transparent, and the mounting structures of the optics clusters are delicate and therefore only produce minimal shadows, this diffuse flow of daylight can be seen as a third contribution to the creation of value of the whole system (electro-thermal light coupling).

This aspect is best shown in FIG. 5.

Here, the optical clusters described are installed under the transparent cover of a greenhouse (13). The carrier (11) allows attachment of the clusters with low shade, which is adaptable to arbitrary structures.

The arrangement, protected by the cover from wind and weather is not exposed to any wind or weathering influences, so that it can be produced with minimum material expenditure and thus at minimum cost.

The electrical current and the heat generated are conveyed out of the greenhouse, so that only the diffuse light reaches the interior of the greenhouse in order to generate the photosynthesis process. Since the photosynthesis only needs a maximum of 200 W/m², which is present in the penumbra generated by the multistage concentrators, the system can make a combined solar power station from a greenhouse, wherein the thermal energy gained in the warm summer months, given long-term storage, can be used to keep the plants warm during the winter.

The multistage concentrators can be configured with high flexibility with regard to concentration, light distribution and separation (direct/diffuse), which makes them highly suitable for integration in multifunctional structures such as greenhouses, architectural enclosures etc.), wherein virtually the entire radiation flow incident on the aperture is used in a cascade of different exploitation methods, so that an overall efficiency of over 80% can be achieved.

1: Solar multistage concentrator, wherein
at least one imaging lens is provided upstream of a non-imaging lens, in such a manner that both lenses are integral parts of a specifically formed, light-transparent dielectric medium.

2: Solar multistage concentrator according to claim 1,
wherein
the imaging lens comprises a spherical calotte, which connects to a wedge-shaped non-imaging lens.

3: Solar multistage concentrator according to claim 1,
, wherein
the primary imaging lens guides the direct sunlight incident perpendicular to its entry aperture inside the transparent dielectric medium, without total internal reflection at the edges with the air, directly into the depth of the system, where it concentrates said sunlight.

4: Solar multistage concentrator according to claim 1, wherein
in the area in which the focal zone of the first lens is formed, the subsequent shape of the second stage takes the form of a non-imaging lens, which guides the pre-concentrated light further into the depth of the system by total internal reflection at its edges with the air.

5: Solar multistage concentrator according to claim 1, wherein
the non-imaging lens is designed in such a way that it re-concentrates the sunlight concentrated by the first stage with spherical aberration, and pre-homogenizes said light in respect of the spherical and the chromatic aberration.

6: Solar multistage concentrator according to claim 1, wherein
in a third optical arrangement, integrally connected to the second stage, the concentrated light is re-homogenized by total reflection at the boundary surfaces between dielectric medium and air with respect to the energy density and chromatic distribution thereof, and the shape of the emission area of the third stage is matched to that of the so-called solar receiver.

7: Solar multistage concentrator according to claim 1, wherein
the solar receiver consists of a photovoltaic concentration cell, which is fixed directly and in a lossless manner onto the emission aperture of the last stage of the arrangement by means of an optical immersion medium.

8: Solar multistage concentrator according to claim 6, wherein
the rear side of the solar cell is cooled by a fluid, which runs through a thin transparent polymer tube, which is pressed mechanically against the solar cell.

9: Solar multistage concentrator according to claim 1, wherein
the concentrated sunlight diverges in a directed manner into an optically coupled transparent double plate after leaving through the end aperture.

10: Solar multistage concentrator according to claim 1, wherein
a transparent optical cooling fluid flows through the double plate, and wherein
at an appropriate distance from the diverging bundle of rays, a concentrator solar cell is located in this fluid.

11: Solar multistage concentrator according to claim 1, wherein
the solar cell ends in a metallic support with good thermal conductivity on the reverse side of the plate, which is assembled as an electronic printed circuit, and guides the current flow from the cell into this electronic circuit.

12: Solar multistage concentrator according to claim 1, wherein
the first stage consists of an imaging lens which deviates from spherical form in an arbitrary way, and wherein the downstream stage(s) is/are constructed as non-imaging concentrators or homogenizers, respectively, in such a way that the solar receiver used receives the concentrated sunlight in the desired energy density distribution on the entry aperture thereof which is optically directly coupled into the end stage.

13: Solar multistage concentrator according to claim 1, wherein
the sunlight is either concentrated one-dimensionally in focal lines or two-dimensionally in focal points, wherein in the first case a uniaxial and in the second case a biaxial solar tracking system is required.

14: Solar multistage concentrator according to claim 1, wherein
up to a specific range, angular deviations in the solar tracking system are compensated by the non-imaging stages reflecting the resulting inclined solar radiation paths back into the arrangement.

15: Solar multistage concentrator according to claim 1, wherein
the diffuse component of the sunlight radiates through the lateral flanks of the arrangement into the space thereunder.

16: Solar multistage concentrator according to claim 1, wherein multiple concentrators are combined to discs.

17: Solar multistage concentrator according to claim 1, wherein
the one-dimensional or two-dimensional imaging discs, located behind transparent covers such as windows, facade roofs or greenhouse shells, convert the direct solar radiation into useful energy (electricity, chemical energy or heat), whereas the diffuse sunlight is used for illuminating the areas behind or under the arrangement.

18: Solar multistage concentrator according to claim 1, wherein
the lenses are made of highly transparent optical materials, of as high a refractive index as possible, that are non-reflective at the entry and emission apertures, and wherein the total internal reflections occur at the boundary surface between the optical material and air.

19: Solar multistage concentrator according to claim 1, wherein
the lenses consist of transparent hollow bodies, which are likewise filled with highly transparent optical fluids.

20: Solar multistage concentrator according to claim 1, wherein
the transparent walls consist of fluoropolymers with a low refractive index, and the fluid, e.g. silicone oil, has a high refractive index, so that total internal reflection takes place at the boundary between the oil and fluoropolymer.

21: Solar multistage concentrator according to claim 1, wherein
the walls consist of fluoropolymers and the fluid, typically a fluoric liquid or water, also has a low refractive index, so that total internal reflection occurs at the boundary between the cover and air.

22: Greenhouse with a solar multistage concentrator according to claim 1, in particular with a plurality of such solar multistage concentrators.
